(19) United States
(12) Patent Application Publication
(10) Pub. No.: US 2007/0137781 A1
(43) Pub. Date: Jun. 21, 2007

(54) PACKAGE METHOD OF ORGANIC ELECTROLUMINESCENT DEVICE

(76) Inventors: Ping-Tsung Huang, Banchiau City (TW); Hsia-Tsai Hsiao, Miaoli (TW); Yu-Kai Han, Yunlin (TW); Tung-Sheng Cheng, Kaohsiung (TW); Yen-Hua Lin, Hsinchu (TW)

Correspondence Address: J.C. Patents, 4 Venture, Suite 250, Irvine, CA, 92618, US

(21) Appl. No.: 11/621,484

(22) Filed: Jan. 9, 2007

Related U.S. Application Data
(62) Division of application No. 10/869,004, filed on Jun. 15, 2004.

(51) Int. Cl. H01L 51/56

(52) U.S. Cl. 156/275.5; 427/66; 438/26

(57) ABSTRACT

A method of packaging an organic electroluminescent (OEL) device is provided. In the method, a substrate comprising an OEL component formed thereon is provided first. Thereafter, a cover plate is provided. Afterward, a hydrophilic polymer serving as a desiccant between the substrate and the cover plate is formed. Then, an adhesive between the substrate and the cover plate for sealing the OEL component and the desiccant is formed. Therefore, moisture/oxygen in the package structure is absorbed and removed by the hydrophilic polymer.

### CROSS-REFERENCE TO RELATED APPLICATION

This application is a divisional of a prior application Ser. No. 10/869,004, filed Jun. 15, 2004. All disclosures are incorporated herewith by reference.

### BACKGROUND OF THE INVENTION

1. Field of the Invention

The present invention relates to a method of packaging an organic electroluminescent (OEL) device. More particularly, the present invention relates to a method of packaging an OEL device using hydrophilic polymer as desiccant.

2. Description of Related Art

As the development of the semiconductor process advances, display device has become a main stream of electronic device. For example, portable display device has been well developed and adopted in a variety of appliances such as mobile phone, personal digital assistant (PDA) and notebook. Flat panel display (FPD) serves as a communication interface between user and portable device. It is so important that a good portable device will heavily depend on a good display panel.

Flat panel display can be classified into plasma display panel (PDP), liquid crystal display (LCD), inorganic electro-luminescent display, light emitting diode (LED), vacuum fluorescence display (VFD), field emission display (FED), and electro-chromic display. Compared to other flat panel display (FPD) technology, the organic electroluminescent (OEL) device has the advantages of self-luminescence, wide viewing angle, low power consumption, simple manufacturing processes, low manufacturing cost, low operation temperature, and short response time, etc. Therefore, the OEL device has been developed by a variety of manufactures in recent years and has become a main stream of next generation flat panel display.

The OEL device utilizes self-luminescence characteristic of organic functional material for displaying images. The organic functional materials are classified into small molecular OEL (SM-OEL) material and polymeric OEL (POEL) material according to the molecular weight thereof. The structure of emitting light of the OEL device conventionally includes a pair of electrodes and an organic functional material layer. Electrons and holes in the organic functional material layer are recombined to generate excitons while a current is applied between the transparent anode and metal cathode. Light is, therefore, generated by the energy released from excitons. Wherein the color of the light is dependent on the characteristic of the organic functional material.

FIG. 1 is a schematic cross-sectional view illustrating package structure of a conventional OEL device. Referring to FIG. 1, a package structure of a conventional OEL device includes a substrate 100, an organic electroluminescent (OEL) component 110, a cover plate 120, a desiccant 130 and a frame sealant 140. The OEL component 110 is disposed over the substrate 100. The desiccant 130 is disposed above the cover plate 120. The substrate 100 and the cover plate 120 are assembled by using the frame sealant 140, wherein the OEL component 110 and the desiccant 130 are sealed between the substrate 100 and the cover plate 120.

In general, a degradation of OEL components leads to formation of dark spots. Therefore, in order to enhance the durability of the OEL component, the generation of the dark spot must be reduced. It is noted that the material of the frame sealant 140 is incapable for completely preventing the infiltration of moisture and oxygen from the external environment. In addition, the organic functional material of the OEL component 110 and the cathode are easily reacted with moisture and oxygen and fonn dark spots. In general, as described above, the desiccant 130 is provided for removing the moisture and the oxygen that infiltrate into the package structure of the OEL device. In general, the conventional desiccant 130 may be classified into solid or liquid desiccant. The solid desiccant is generally composed of zeolite. The zeolite is a solid material composed of a plurality of holes, and the percentage of the moisture removed from the air is about 13%. The liquid desiccant is generally a solvent including aluminum, and the percentage of the moisture removed from the air is less than 10%. However, the solid or the liquid desiccant has the following disadvantages.

First, if the desiccant is a solid desiccant (e.g., including zeolite), the OEL component may be damaged or scrubbed during the process of package. Next, if the desiccant is a liquid desiccant (e.g., a solvent including aluminum), the solvent of the desiccant must be baked for a long time (in general about 2 hours). In addition, some byproducts (e.g., oxide of aluminum) may be generated as a result of reaction between the moisture aluminum contained in the solvent. Therefore, the byproducts may damage the OEL component.

Accordingly, a method of packaging the OEL component is disclosed in U.S. Pat. No. 6,226,890, wherein a desiccant composed of mixture of desiccant particles and binders is provided for removing the infiltrated moisture and oxygen in the package structure. The desiccant described above may be manufactured as follows. First, the desiccant particles and the liquid binder are mixed together. Next, the liquid desiccant is coated on the cover plate of the package structure. Finally, the liquid desiccant coated on the cover plate is baked to form a solid thin film.

Since some of the desiccant particles are covered by the binders of the solid thin film, a part of the moisture and the oxygen infiltrated in the package structure can not be absorbed rapidly and effectively by the desiccant of the solid thin film. In other words, the OEL component may be damaged by moisture and oxygen within the package structure due to the low efficiency of the desiccant particles. Furthermore, as the thickness of the OEL component of the flat panel display device increases gradually, the amount of the solid particles of the desiccant is limited. Therefore, the moisture and oxygen removal efficiency of the desiccant for the flat panel display must be high enough. However, the efficiency of the conventional desiccant particles is not sufficiently high enough in removing moisture and oxygen within the package structure to protect OEL component of the flat panel display from damage.

### SUMMARY OF THE INVENTION

Accordingly, the present invention provided a package structure of an organic electroluminescent (OEL) device and a method of packaging an organic electroluminescent (OEL) device. The moisture or oxygen within the package structure, according to an embodiment of the present invention, can be efficiently removed. Therefore, the generation of dark spots can be effectively reduced, and the lifetime of the OEL device can be effectively enhanced.

In accordance with one embodiment of the present invention, a package structure of an OEL device comprises, for example but not limited to, a substrate, an OEL component, a cover plate, a desiccant and an adhesive. The OEL component is disposed over the substrate. The cover plate is disposed over the substrate. The desiccant is disposed above the substrate or the cover plate. The desiccant includes, for example but not limited to, a hydrophilic polymer. The adhesive is disposed between the substrate and the cover plate, wherein the OEL component and the desiccant are sealed by the substrate, the cover plate and the adhesive.

In one embodiment of the present invention, the OEL component includes, for example but not limited to, a first electrode, a second electrode and an organic functional layer. The first electrode includes, for example but not limited to, a transparent electrode. The second electrode includes, for example but not limited to, a metal electrode. The first electrode is disposed above the substrate. The second electrode is disposed over the first electrode. The organic functional layer is disposed between the first electrode and the second electrode. The organic functional layer includes, for example but not limited to, a light-emitting layer. In addition, a hole-injecting layer and a hole-transporting layer may be disposed between the first electrode and the light-emitting layer optionally. Moreover, an electron-transporting layer and an electron-injecting layer may also be optionally disposed between the second electrode and the light-emitting layer.

In one embodiment of the present invention, the desiccant may be disposed above the plate surface. Alternatively, a groove may be formed on the cover plate and then the desiccant is disposed in the groove. Accordingly, the total thickness of the package structure can be reduced.

In one embodiment of the present invention, a material of the substrate or a material of the cover plate includes, for example but not limited to, glass, plastic or metal. The moisture removal efficiency of the hydrophilic polymer from air is greater than 3%. The hydrophilic polymer comprises a material selected from the group consisting of anionic polymer and its derivatives, cationic polymer and its derivatives, cellulose polymer and its derivatives, cellulose and its derivatives, polyaniline and its derivatives, Dextran, Dextran sulfate, Dextran sodium salt, Dextran DEAE ether, poly(1-glycerol methacrylate), poly(2-ethyl-2oxazoline), poly(2-hydroxypropyl methacrylate), poly(2-vinylpyridine), poly(2-vinylpyridine N-oxide), poly(4-vinylpyridine N-oxide), poly(N-vinylpyrrolidone), poly(acrylamide/2-methacryloxyethyltrimethylammonium bromide), poly(acrylamide-co-acrylic acid), poly(acrylic acid) ammonium salt, poly(acrylic acid) sodium salt, poly(acrylic acid), poly(butadiene-co-maleic acid), poly(ethylene glycol), poly(ethylene glycol) monomethyl ether, poly(ethylene oxide), poly(ethylene oxide-b-propylene oxide), poly(ethylene-co-acrylic acid), poly(itaconic acid), poly(I-lysine hydrobromide), poly(maleic acid), poly(methacrylic acid) ammonium salt, poly(methacrylic acid) sodium salt, poly (n-butyl acrylate-co-2-methacrloxyethyltrimethylammonium bromide), poly(N-isopropylacrylamide), poly(vinylacetate) and its hydrolyzed polymers, poly(vinyl alcohol), poly(vinylmethylether), poly(vinylphosphonic acid), poly(vinylsulfonic acid) and its sodium salt, poly(acrylamide), poly(aniline), polyethyleneimine, and polymethacrylamide.

In one embodiment of the present invention, the anionic polymer and its derivatives comprises a material selected from the group consisting of polystyrenesulfonic acid and its lithium, sodium, potassium and ammonium salt, copolymers of styrenesulfonic acid with acrylamide, methylacrylate, dimethylamino ethylmethacrylate, acrylate, and dimethyl-acrylamide and their alkali salts, sulfonated cellulose and its alkali salts, copolymer of 2-acrylamido-2-methyl-1-propanesulfonic acid with acrylamide, methylacrylate, dimethylaminoethyl-methacrylate, acrylate, dimethylacrylamide, and its sodium, potassium and cesium salt.

In one embodiment of the present invention, the cationic polymer and its derivatives comprises a material selected from the group consisting of poly(vinylbentrimethylammonium chloride), polyvinylpyrrolidonedimethylaminoethyl methylacrylate copolymer quaterized with diethyl sulfate, (trimethyl ammonium) propylmethacrylamide methyl sulfate and (trimethyl ammonium) ethylmethacrylamide methyl sulfate.

In one embodiment of the present invention, the cellulose polymer and its derivatives comprises a material selected from the group consisting of cellulose-carboxymethyl ether and its sodium salt, cellulose-ethyl ether, cellulose-hydroxyethyl ether, cellulose-ethyl hydroxyethyl ether and cellulose-methyl hydroxyethel ether.

In one embodiment of the present invention, the adhesive comprises thermal hardening resin or ultraviolet light hardening resin.

In accordance with one embodiment of the present invention, the method of packaging organic electroluminescent (OEL) device comprises a substrate, having an organic electroluminescent (OEL) component formed thereon. Next, a cover plate is provided. Next, a hydrophilic polymer is formed between the substrate and the cover plate as a desiccant. Next, an adhesive is formed between the substrate and the cover plate to seal the OEL component and the desiccant.

In one embodiment of the present invention, a method of forming the desiccant includes the following steps. First, a hydrophilic polymer is formed above the substrate or the cover plate. Thereafter, the hydrophilic polymer is cured or crosslinked. In one embodiment of the present invention, the hydrophilic polymer is cured by baking the hydrophilic polymer at a temperature of about 100° C. to about 230° C. for about at least 3 minutes.

Accordingly, in the present invention, the hydrophilic polymer is provided as the desiccant in the package structure of the OEL device. Since the hydrophilic polymer is hydrophilic, moisture or oxygen in the package structure will be readily removed. Therefore, the generation of the dark spots can be effectively reduced, and the lifetime of the OEL device can be effectively enhanced.

One or part or all of these and other features and advantages of the present invention will become readily apparent to those skilled in this art from the following description wherein there is shown and described a preferred embodiment of this invention, simply by way of illustration of one of the modes best suited to carry out the invention. As it will be realized, the invention is capable of different embodiments, and its several details are capable of modifications in various, obvious aspects all without departing from the invention. Accordingly, the drawings and descriptions will be regarded as illustrative in nature and not as restrictive.

### BRIEF DESCRIPTION OF THE DRAWINGS

The accompanying drawings are included to provide a further understanding of the present invention, and are incorporated in and constitute a part of this specification. The drawings illustrate embodiments of the present invention and, together with the description, serve to explain the principles of the present invention.

FIG. 1 is a schematic cross-sectional view illustrating a package structure of a conventional OEL device.

FIG. 2 is a flowchart illustrating a method of packaging an organic electroluminescent (OEL) component according to one embodiment of the present invention.

FIG. 3A is a schematic cross-sectional view illustrating a package structure of an OEL device according to one embodiment of the present invention.

FIG. 3B is a schematic cross-sectional view illustrating a package structure of an OEL device according to another embodiment of the present invention.

FIG. 4 is a diagram illustrating a removed moisture percentage of an OEL device according to another embodiment of the present invention.

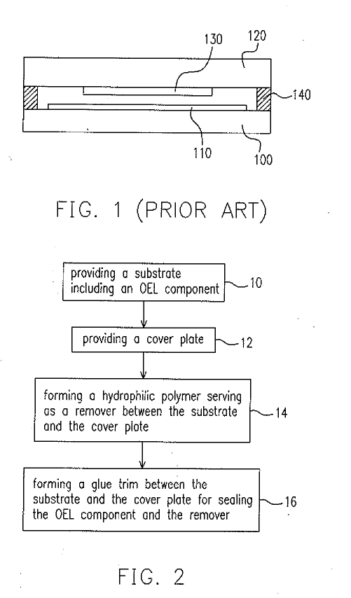

### DESCRIPTION OF THE EMBODIMENTS

The present invention will be described fully hereinafter with reference to the accompanying drawings, in which preferred embodiments of the present invention are illustrated. The present invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements in the accompanying drawings throughout.

FIG. 2 is a flowchart illustrating a method of packaging an organic electroluminescent (OEL) component according to one embodiment of the present invention. Referring to FIG. 2, at step 10, a substrate having an organic electroluminescent (OEL) component formed thereon is provided. Thereafter, at step 12, a cover plate is provided. In one embodiment of the present invention, the substrate and the cover plate may be composed of, for example but not limited to, glass, plastic or metal. Then, at step 14, a hydrophilic polymer is formed between the substrate and the cover plate and used as a desiccant. The moisture removal efficiency of the hydrophilic polymer from air is larger than 3%. The hydrophilic polymer comprises, for example but not limited to, anionic polymer its ion derivatives, cationic polymer and its derivatives, cellulose polymer and its derivatives, polyaniline and its derivatives, Dextran, Dextran sulfate, Dextran sodium salt, Dextran DEAE ether, poly(1-glycerol methacrylate), poly(2-ethyl-2oxazoline), poly(2-hydroxypropyl methacrylate), poly(2-vinylpyridine), poly(2-vinylpyridine N-oxide), poly(4-vinylpyridine N-oxide), poly(N-vinylpyrrolidone), poly(acrylamide/2-methacryloxyethyltrimethylammonium bromide), poly(acrylamide-co-acrylic acid), poly(acrylic acid) ammonium salt, poly(acrylic acid) sodium salt, poly(acrylic acid), poly(butadiene-co-maleic acid), poly(ethylene glycol), poly(ethylene glycol) monomethyl ether, poly(ethylene oxide), poly(ethylene oxide-b-propylene oxide), poly(ethylene-co-acrylic acid), poly(itaconic acid), poly(1-lysine hydrobromide), poly(maleic acid), poly(methacrylic acid) ammonium salt, poly(methacrylic acid) sodium salt, poly (n-butyl acrylate-co-2-methacrloxyethyltrimethylammonium bromide), poly(N-isopropylacrylamide), poly(vinylacetate) and its hydrolyzed polymers, poly(vinyl alcohol), poly(vinylmethylether), poly(vinylphosphonic acid), poly(vinylsulfonic acid) and its sodium salt, poly(acrylamide), poly(aniline), polyethyleneimine and polymethacrylamide.

In one embodiment of the present invention, the anionic polymer and its derivatives comprises, for example but not limited to, polystyrenesulfonic acid and its lithium, sodium, potassium and ammonium salt, copolymers of styrenesulfonic acid with acrylamide, methylacrylate, dimethylamino ethylmethacrylate, acrylate, dimethyl-acrylamide and their alkali salts, sulfonated cellulose and its alkali salts, copolymer of 2-acrylamido-2-methyl-1-propanesulfonic acid with acrylamide, methylacrylate, dimethylaminoethyl-methacrylate, acrylate, dimethylacrylamide, and its sodium, potassium, and cesium salt.

In one embodiment of the present invention, the cationic polymer and its derivatives comprises, for example but not limited to, poly(vinylbentrimethylammonium chloride), polyvinylpyrrolidonedimethylaminoethyl methylacrylate copolymer quaterized with diethyl sulfate, (trimethyl ammonium) propylmethacrylamide methyl sulfate, and (trimethyl ammonium) ethylmethacrylamide methyl sulfate.

In one embodiment of the present invention, the cellulose polymer and its derivatives comprises, for example but not limited to, cellulose-carboxymethyl ether and its sodium salt, cellulose-ethyl ether, cellulose-hydroxyethyl ether, cellulose-ethyl hydroxyethyl ether, and cellulose-methyl hydroxyethel ether.

In one embodiment of the present invention, a method of forming the desiccant comprises, for example but not limited to, the following steps. First, a hydrophilic polymer is formed above the cover plate. Thereafter, the hydrophilic polymer is cured by, for example but not limited to, baking the cover plate in a low moisture and low oxygen environment at a temperature of about 100° C. to about 230° C. perform for at least 3 minutes. Finally, at step 16, an adhesive is formed between the substrate and the cover plate to seal the OEL component and the desiccant. The method of forming the adhesive between the substrate and the cover plate comprises, for example but not limited to, the following steps. First, the adhesive is formed on the substrate, then, the cover plate is pressed laminated on the substrate. Alternatively, the adhesive may be first formed on the cover plate, and then the cover plate is laminated on the substrate. The adhesive may be comprised of, for example but not limited to, thermal hardening resin or ultraviolet light hardening resin.

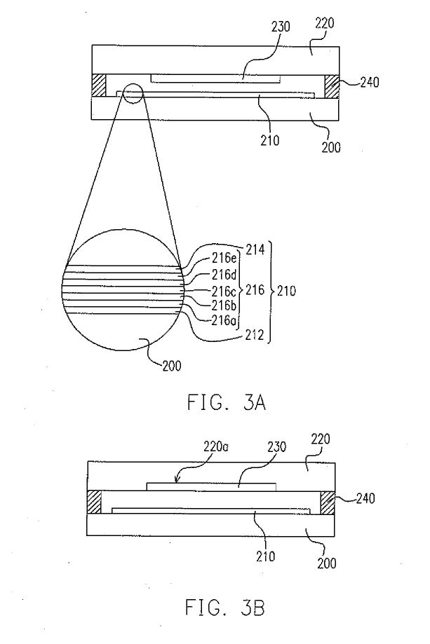

FIG. 3A is a schematic cross-sectional view illustrating a package structure of an OEL device according to one embodiment of the present invention. Referring to FIG. 3A, a package structure of an organic electroluminescent (OEL) component comprises, for example but not limited to, a substrate 200, an organic electroluminescent (OEL) component 210, a cover plate 220, a desiccant 230 and an adhesive 240.

The OEL component 210 is disposed over the substrate 200. The OEL component 210 comprises, for example but not limited to, a first electrode 212, a second electrode 214 and an organic functional layer 216. The first electrode 212 comprises, for example but not limited to, a transparent electrode. The second electrode 214 comprises, for example but not limited to, a metal electrode. The first electrode 212 is disposed above the substrate 200, and the second electrode 214 is disposed over the first electrode 212. The organic functional layer 216 is disposed between the first electrode 212 and the second electrode 214.

The organic functional layer 216 comprises, for example but not limited to, a multilayer organic thin film comprising, for example, a hole-injecting layer 216a, a hole-transporting layer 216b, a elight-emitting layer 216c, an electron transporting layer 216d and an electron injecting layer 216e. It should be noted that, since a light emitted by the OEL display device 210 is mainly generated by the light-emitting layer 216c, therefore the hole-injecting layer 216a, the hole-transporting layer 216b, the electron-transporting layer 216d and the electron-injecting layer 216e may optionally be formed.

As shown in FIG. 3A, the cover plate 220 is disposed over the substrate 200, and the desiccant 230 is disposed above the cover plate 220. The desiccant 230 may be composed of, for example but not limited to, hydrophilic polymer. The adhesive 240 is disposed between the substrate 200 and the cover plate 220, wherein the OEL component 210 and the desiccant 230 are sealed by the substrate 200, the cover plate 220 and the adhesive 240.

FIG. 3B is a schematic cross-sectional view illustrating a package structure of an OEL device according to another embodiment of the present invention. The package structure shown in FIG. 3B is similar to that shown in FIG. 3A, and the difference there-between is that in FIG. 3B, a groove 220a is disposed on the cover plate 220, and the desiccant 230 is disposed in the groove 220a. Therefore, the total thickness of the package structure can be reduced.

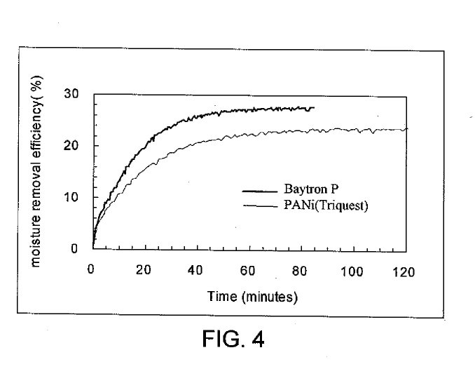

In one embodiment of the present invention, the hydrophilic polymer is provided to serve as the desiccant of the OEL component of the package structure. Since the hydrophilic polymer is hydrophilic, the moisture or oxygen in the package structure can be absorbed the hydrophilic polymer. The hydrophilic polymer may be activated by a thermal treatment such as baking. As shown in Table 1 listed below and FIG. 4, the hydrophilic polymer, according to an embodiment of the present invention, comprises Baytron P, and the moisture removal efficiency of Baytron P (baked and cool in air) from air is about 27%. Alternatively, the hydrophilic polymer, according to an embodiment of the present invention, comprises PANi(Triquest), and the moisture removal efficiency of PANi(Triquest) (baked and cooled in air) from air is about 23%. Accordingly, the water/moisture/oxygen removal efficiency of the Hydrophilic polymer of the present invention is several folds better than that of the conventional solid or liquid desiccant.

TABLE 1

Moisture
removal efficiency (%)

| Time (minutes) | Baytron P | PANi(Triquest) |
|---|---|---|
| 1 | 4.3 | 3.4 |
| 2 | 5.7 | 5.0 |
| 3 | 7.2 | 5.9 |
| 4 | 8.0 | 6.9 |
| 5 | 9.0 | 7.8 |
| 10 | 13.4 | 10.8 |
| 20 | 20.0 | 15.8 |
| 60 | 27.0 | 23.0 |

In addition, since the film-forming property of the hydrophilic polymer is excellent, the OEL component will not get damaged or scratched during the package process. Moreover, the baking process time is very short (generally only about 3 minutes). In addition, the moisture/oxygen absorbed by the hydrophilic polymer do not produce byproduct, and therefore damage of the OEL component due to moisture/oxygen within the package structure can be effectively reduced.

It should be noted that, in the embodiments of the present invention, the hydrophilic polymer is adapted for removing the moisture within the package structure of the OEL device. However, the hydrophilic polymer or appropriate polymer(s) may also be applied for removing moisture or gases with a view of improving the reliability of semiconductor devices.

Accordingly, the present invention has at least the following advantages. First, the water/oxygen/moisture removal efficiency of the hydrophilic polymer of the present invention far more superior than that of the conventional solid or liquid desiccant. Therefore, the hydrophilic polymer of the present invention is capable of reducing generation of dark spots and promoting the lifetime of the OEL device.

In addition, the film-forming property of the hydrophilic polymer is excellent, the OEL component will not get damaged or scratched during the package process. Furthermore, the OEL component may still operate normally even when the desiccant gets damaged.

Moreover, the baking process time is very short (generally only about 3 minutes).

Further, the moisture absorbed by the hydrophilic polymer does not produce any byproduct that damage the OEL component.

The foregoing description of the preferred embodiment of the present invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A method of packaging an organic electroluminescent (OEL) device, comprising:
providing a substrate, comprising an OEL component formed thereon;
providing a cover plate;
forming a hydrophilic polymer serving as a desiccant between the substrate and the cover plate; and
forming an adhesive between the substrate and the cover plate for sealing the OEL component and the desiccant.

2. The method of claim 1, wherein the step of forming the desiccant comprises:
forming the hydrophilic polymer above the cover plate; and
curing or crosslinking the hydrophilic polymer.

3. The method of claim 2, wherein the hydrophilic polymer is cured at a temperature of about 100° C. to about 230° C.

4. The method of claim 1, wherein the cover plate further comprises a groove, wherein the desiccant is disposed in the groove.

5. The method of claim 1, wherein a moisture removal efficiency of the hydrophilic polymer from air is larger than 3%.

6. The method of claim 5, wherein the hydrophilic polymer comprises a material selected from cationic polymer and its derivatives

7. The method of claim 6, wherein the cationic polymer and its derivatives comprises a material selected from the group consisting of poly(vinylbentrimethylammonium chloride), polyvinylpyrrolidonedimethylaminoethyl methylacrylate copolymer quaterized with diethyl sulfate, (trimethyl ammonium) propylinethacrylamide methyl sulfate and (trimethyl ammonium) ethylmethacrylamide methyl sulfate.
